(19) United States
(12) Patent Application Publication
(10) Pub. No.: US 2025/0380513 A1
(43) Pub. Date: Dec. 11, 2025

(54) Electrostatic discharge protection circuit and voltage detection circuit thereof

(71) Applicant: REALTEK SEMICONDUCTOR CORPORATION, Hsinchu (TW)

(72) Inventor: Chung-yu HUANG, Hsinchu (TW)

(21) Appl. No.: 19/210,311

(22) Filed: May 16, 2025

(30) Foreign Application Priority Data
Jun. 7, 2024 (TW) 113121376

(51) Int. Cl. H10D 89/60

(52) U.S. Cl. CPC H10D 89/819

(57) ABSTRACT

A voltage detection circuit is provided. A first and a second detection inverters of a detection circuit outputs an inverted detection signal and an output detection signal to a first and a second detection output terminals. A feedback detection circuit outputs an inverted feedback detection signal. A first transistor is coupled between the first detection output terminal and a ground terminal. A second transistor is coupled between the second detection output terminal and a first gate. A second gate is controlled by the inverted feedback detection signal. A third transistor is coupled between the first gate and the ground terminal. A third gate is controlled by the inverted feedback detection signal. The detection signal at a high state makes the inverted feedback detection signal turn on the second transistor and turn off the third transistor such that the first transistor turns on.

### BACKGROUND OF THE INVENTION

### 1. Field of the Invention

The present disclosure relates to an electrostatic discharge protection circuit and a voltage detection circuit thereof.

### 2. Description of Related Art

Voltage detection technology can be used in such as, but not limited to an electrostatic discharge (ESD) protection circuit. Since electrostatic discharge may cause permanent damage to electronic components and equipments, integrated circuit products may be equipped with electrostatic discharge protection components or circuits along with a test operation to increase the ability to protect the integrated circuit products from being damaged by the electrostatic discharge, so as to further increase the yield of the products. The stability of the voltage detection circuit especially determines whether the electrostatic discharge protection circuit provides a sufficient discharging time and whether the electrostatic discharge protection circuit turns off completely after the discharging is performed.

### SUMMARY OF THE INVENTION

In consideration of the problem of the prior art, an object of the present disclosure is to provide an electrostatic discharge protection circuit and a voltage detection circuit thereof.

The present invention discloses a voltage detection circuit that includes an electrostatic detection circuit, a feedback detection circuit, a first transistor, a second transistor and a third transistor. The electrostatic detection circuit includes a first detection inverter and a second detection inverter. The first detection inverter is configured to receive and invert a detection signal from a detection input terminal to output an inverse detection signal to a first detection output terminal. The second detection inverter is configured to receive and invert the inverse detection signal from the first detection output terminal to output an output detection signal to a second detection output terminal. The feedback detection circuit is configured to receive and invert the detection signal to output an inverse feedback detection signal. The first transistor is electrically coupled between the first detection output terminal and a ground terminal. The second transistor is electrically coupled between the second detection output terminal and a first gate of the first transistor, and a second gate of the second transistor is controlled by the inverse feedback detection signal. The third transistor is electrically coupled between the first gate and ground terminal, wherein a third gate of the third transistor is controlled by the inverse feedback detection signal. When the detection signal is at a high state, the inverse feedback detection signal controls the second transistor to turn on and controls the third transistor to turn off, and the second transistor transmits the output detection signal to the first gate to control the first transistor to turn on. When the detection signal is at a low state, the inverse feedback detection signal controls the second transistor to turn off and controls the third transistor to turn on, and the third transistor discharges the first gate to control the first transistor to turn off.

The present invention also discloses an electrostatic discharge protection circuit that includes a voltage-dividing circuit, a voltage detection circuit, a first inverter, a second inverter, a RC circuit, a first switch circuit, a second switch circuit, a first discharging transistor and a second discharging transistor. The voltage-dividing circuit is electrically coupled to a voltage input terminal to generate a detection signal at a detection input terminal, wherein the voltage input terminal is further electrically coupled to a first voltage feeding terminal configured to feed a first voltage. The voltage detection circuit includes an electrostatic detection circuit, a feedback detection circuit, a first transistor, a second transistor and a third transistor. The electrostatic detection circuit includes a first detection inverter and a second detection inverter. The first detection inverter is configured to receive and invert a detection signal from a detection input terminal to output an inverse detection signal to a first detection output terminal. The second detection inverter is configured to receive and invert the inverse detection signal from the first detection output terminal to output an output detection signal to a second detection output terminal. The feedback detection circuit is configured to receive and invert the detection signal to output an inverse feedback detection signal. The first transistor is electrically coupled between the first detection output terminal and a ground terminal. The second transistor is electrically coupled between the second detection output terminal and a first gate of the first transistor, and a second gate of the second transistor is controlled by the inverse feedback detection signal. The third transistor is electrically coupled between the first gate and ground terminal, wherein a third gate of the third transistor is controlled by the inverse feedback detection signal. When the detection signal is at a high state, the inverse feedback detection signal controls the second transistor to turn on and controls the third transistor to turn off, and the second transistor transmits the output detection signal to the first gate to control the first transistor to turn on. When the detection signal is at a low state, the inverse feedback detection signal controls the second transistor to turn off and controls the third transistor to turn on, and the third transistor discharges the first gate to control the first transistor to turn off. The first inverter has a first inverter input terminal and a first inverter output terminal and is electrically coupled between the first voltage feeding terminal and a second inverter input terminal. The second inverter has the second inverter input terminal and a second inverter output terminal and is electrically coupled between the first inverter output terminal and the ground terminal. The RC circuit includes a resistor and a capacitor circuit, wherein the capacitor circuit is electrically coupled to the first voltage feeding terminal through the resistor to be charged accordingly and provides electric charges to the first inverter input terminal and the second inverter input terminal. The first switch circuit is electrically coupled between one the first inverter input terminal and the second inverter input terminal and the ground terminal. The second switch circuit is electrically coupled between a second voltage feeding terminal configured to feed a second voltage and the second inverter input terminal. The first discharging transistor and the second discharging transistor are electrically coupled in series between the first voltage feeding terminal and the ground terminal, and are respectively controlled by voltages of the first inverter output terminal and the second inverter output terminal. The output detection signal controls the first switch circuit to turn on and controls the second switch circuit to turn off when an electrostatic discharge input occurs to the voltage input terminal, such that the first discharging transistor and the second discharging transistor turn on to discharge the voltage input terminal.

The present invention also discloses an electrostatic discharge protection circuit that includes a voltage-dividing circuit, a voltage detection circuit, a first inverter, a second inverter, an inverter control circuit, a first switch circuit, a second switch circuit, a first discharging transistor and a second discharging transistor. The voltage-dividing circuit is electrically coupled to a voltage input terminal to generate a detection signal at a detection input terminal, wherein the voltage input terminal is further electrically coupled to a first voltage feeding terminal configured to feed a first voltage. The voltage detection circuit includes an electrostatic detection circuit, a feedback detection circuit, a first transistor, a second transistor and a third transistor. The electrostatic detection circuit includes a first detection inverter and a second detection inverter. The first detection inverter is configured to receive and invert a detection signal from a detection input terminal to output an inverse detection signal to a first detection output terminal. The second detection inverter is configured to receive and invert the inverse detection signal from the first detection output terminal to output an output detection signal to a second detection output terminal. The feedback detection circuit is configured to receive and invert the detection signal to output an inverse feedback detection signal. The first transistor is electrically coupled between the first detection output terminal and a ground terminal. The second transistor is electrically coupled between the second detection output terminal and a first gate of the first transistor, and a second gate of the second transistor is controlled by the inverse feedback detection signal. The third transistor is electrically coupled between the first gate and ground terminal, wherein a third gate of the third transistor is controlled by the inverse feedback detection signal. When the detection signal is at a high state, the inverse feedback detection signal controls the second transistor to turn on and controls the third transistor to turn off, and the second transistor transmits the output detection signal to the first gate to control the first transistor to turn on. When the detection signal is at a low state, the inverse feedback detection signal controls the second transistor to turn off and controls the third transistor to turn on, and the third transistor discharges the first gate to control the first transistor to turn off. The first inverter has a first inverter input terminal and a first inverter output terminal and is electrically coupled between the first voltage feeding terminal and a second inverter input terminal. The second inverter has the second inverter input terminal and a second inverter output terminal and is electrically coupled between the first inverter output terminal and the ground terminal. The inverter control circuit is configured to operate according to the first voltage to perform voltage boosting on the output detection signal and generate a control signal having a phase inverse to the output detection signal to the first inverter input terminal. The first switch circuit is electrically coupled between one the first inverter input terminal and the second inverter input terminal and the ground terminal. The second switch circuit is electrically coupled between a second voltage feeding terminal configured to feed a second voltage and the second inverter input terminal. The first discharging transistor and the second discharging transistor are electrically coupled in series between the first voltage feeding terminal and the ground terminal, and are respectively controlled by voltages of the first inverter output terminal and the second inverter output terminal. The output detection signal controls the first switch circuit to turn on and controls the second switch circuit to turn off when an electrostatic discharge input occurs to the voltage input terminal, such that the first discharging transistor and the second discharging transistor turn on to discharge the voltage input terminal.

These and other objectives of the present disclosure will no doubt become obvious to those of ordinary skill in the art after reading the following detailed description of the preferred embodiments that are illustrated in the various figures and drawings.

### BRIEF DESCRIPTION OF THE DRAWINGS

FIG. 1 illustrates a circuit diagram of an electrostatic discharge protection circuit according to an embodiment of the present invention.

FIG. 2 illustrates a more detailed circuit diagram of the voltage detection circuit in FIG. 1 according to an embodiment of the present invention.

FIG. 3A, FIG. 3B and FIG. 3C illustrate detailed circuit diagrams of the voltage detection circuit in FIG. 1 according to another embodiment of the present invention.

FIG. 4A and FIG. 4B illustrate detailed circuit diagrams of the voltage detection circuit in FIG. 1 according to yet another embodiment of the present invention.

FIG. 5 illustrates a detailed circuit diagram of the voltage detection circuit in FIG. 1 according to still another embodiment of the present invention.

FIG. 6 illustrates a circuit diagram of an electrostatic discharge protection circuit according to another embodiment of the present invention.

### DETAILED DESCRIPTION OF THE PREFERRED EMBODIMENTS

An aspect of the present invention is to provide an electrostatic discharge protection circuit and a voltage detection circuit thereof to dispose a first transistor in the voltage detection circuit to increase the electrostatic discharging time and enhance the turn-off of the electrostatic discharge protection mechanism. Further, a feedback detection circuit is disposed to control a second transistor and a third transistor to further control the turn-on and turn-off of a first transistor to prevent the first transistor from falsely turning on in some usage scenarios and from the occurrence of incapability to turn off.

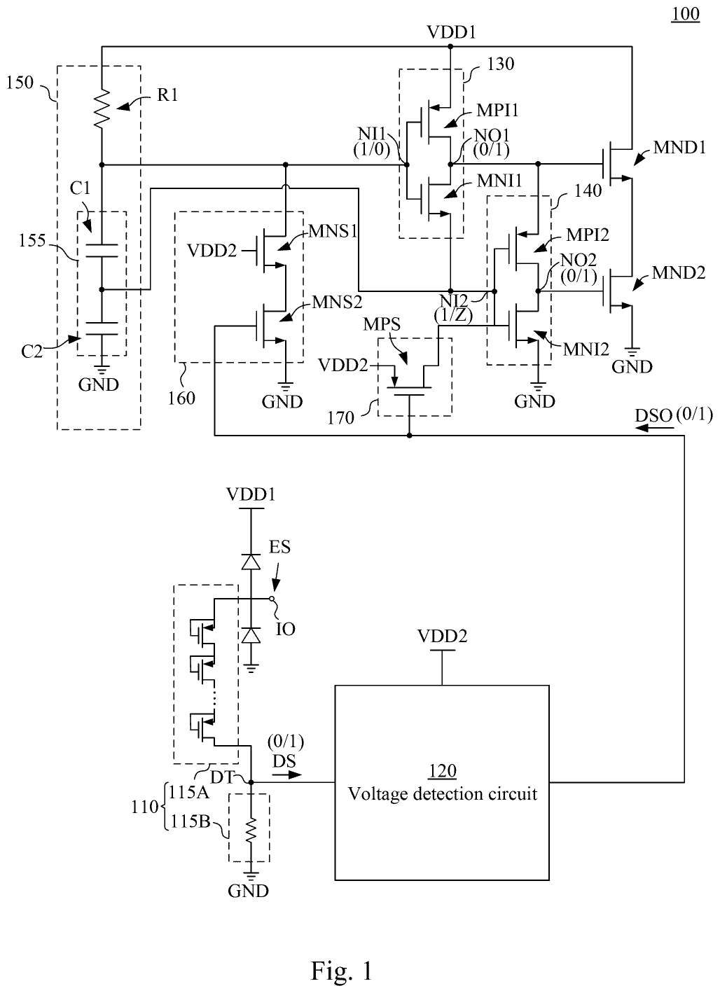

Reference is now made to FIG. 1. FIG. 1 illustrates a circuit diagram of an electrostatic discharge protection circuit 100 according to an embodiment of the present invention. The electrostatic discharge protection circuit 100 includes a voltage-dividing circuit 110, a voltage detection circuit 120, a first inverter 130, a second inverter 140, a RC circuit 150, a first switch circuit 160, a second switch circuit 170, a first discharging transistor MND1 and a second discharging transistor MND2.

The voltage-dividing circuit 110 is electrically coupled to a voltage input terminal IO to generate a detection signal DS at a detection input terminal DT. The voltage input terminal IO can be a power pin configured to receive a power signal or an input/output (I/O) pin configured to receive and deliver a data signal. In an embodiment, the voltage input terminal IO may include one pin or more than one pins coupled in parallel.

In an embodiment, the voltage input terminal IO is further electrically coupled to a first voltage feeding terminal that configured to feed a first operation voltage VDD1. In an embodiment, the first operation voltage VDD1 can be such as, but not limited to 3.3 volts.

In an embodiment, the voltage-dividing circuit 110 includes a first resistive circuit 115A and a second resistive circuit 115B coupled in series through the detection input terminal DT between the voltage input terminal IO and the ground terminal GND. In an embodiment, the electrostatic discharge protection circuit 100 is disposed in an electronic apparatus (not illustrated in the figure) and receives either the power signal or the data signal through the voltage input terminal IO when the electronic apparatus is in operation, so as to generate the detection signal DS at the detection input terminal DT according the resistance ratio between the first resistive circuit 115A and the second resistive circuit 115B.

The voltage detection circuit 120 is configured to operate according to the detection signal DS based on a second operation voltage VDD2 smaller than the first operation voltage VDD1 to generate an output detection signal DSO having the same phase with the detection signal DS. In an embodiment, the second operation voltage VDD2 is such as, but not limited to 1.8 volts and can be generated by dividing the first operation voltage VDD1 or from another independent voltage. The detail configuration of the voltage detection circuit 120 is described in latter paragraphs.

The first inverter 130 has a first inverter input terminal NI1 and a first inverter output terminal NO1. The second inverter 140 has a second inverter input terminal NI2 and a second inverter output terminal NO2.

The first inverter 130 is electrically coupled between the first voltage feeding terminal for feeding the first operation voltage VDD1 and the second inverter input terminal NI2 and includes a P-type transistor MPI1 and an N-type transistor MNI1 electrically coupled in series. The second inverter 140 is electrically coupled between the first inverter output terminal NO1 and the ground terminal GND and includes a P-type transistor MPI2 and an N-type transistor MNI2 electrically coupled in series.

The RC circuit 150 includes a resistor R1 and a capacitor circuit 155. The capacitor circuit 155 is electrically coupled to the first voltage feeding terminal through the resistor R1 to be charged accordingly and provides electric charges to the first inverter input terminal NI1 and the second inverter input terminal NI2. In the present embodiment, the resistor R1 is electrically coupled between the first voltage feeding terminal and the first inverter input terminal NI1. The capacitor circuit 155 includes capacitors C1 and C2 coupled in series, wherein the capacitor C1 is electrically coupled between the first inverter input terminal NI1 and the second inverter input terminal NI2 and the capacitor C2 is electrically coupled between the second inverter input terminal NI2 and the ground terminal GND.

The first switch circuit 160 is electrically coupled between the first inverter input terminal NI1 and a ground terminal GND. In an embodiment, the first switch circuit 160 includes a first N-type switch transistor MNS1 and a second N-type switch transistor MNS2 coupled in series. The first N-type switch transistor MNS1 is controlled by the second operation voltage VDD2 to turn on, and the second N-type switch transistor MNS2 is controlled by the output detection signal DSO.

The second switch circuit 170 is electrically coupled between a second voltage feeding terminal for feeding the second operation voltage VDD2 and the second inverter input terminal NI2. In an embodiment, the second switch circuit 170 includes a P-type switch transistor MPS and is controlled by the output detection signal DSO.

The first discharging transistor MND1 and the second discharging transistor MND2 are electrically coupled in series between the first voltage feeding terminal for feeding the first operation voltage VDD1 and the ground terminal GND, so as to discharge the voltage input terminal IO electrically coupled to the first voltage feeding terminal. The first discharging transistor MND1 is controlled by a voltage of first inverter output terminal NO1. The second discharging transistor MND2 is controlled by a voltage of the second inverter output terminal NO2.

When the voltage of the voltage input terminal IO does not exceed a predetermined level, e.g., when the voltage input terminal IO only receives either the power signal or the data signal without receiving an electrostatic input ES generated due to an actual generation of the electrostatic charges or due to an electrostatic over shoot (EOS), the electrostatic discharge protection circuit 100 operates in a normal operation mode. The detection signal DS generated by the voltage-dividing circuit 110 at the detection input terminal DT is at a low state level (0). The output detection signal DSO is at the low state level (0) due to the operation of the voltage detection circuit 120.

The first switch circuit 160 turns off due to the output detection signal DSO such that the first inverter input terminal NI1 is at a high state level (1) of 3.3 volts since the first operation voltage VDD1 charges the capacitor circuit 155 of the RC circuit 150. The second switch circuit 170 turns on due to the output detection signal DSO such that the second inverter input terminal NI2 has a voltage level of 1.8 volts since the second operation voltage VDD2 charges the second inverter input terminal NI2. For the source of the N-type transistor MNI2, the second inverter input terminal NI2 having the voltage level of 1.8 volts is able to turn on the N-type transistor MNI2 and is thus equivalent to have the high state level (1).

The high state level of the first inverter input terminal NI1 turns off the P-type transistor MPI1 of the first inverter 130 and turns on the N-type transistor MNI1 of the first inverter 130. The logic state of the first inverter output terminal NO1 is the low state since the first inverter 130 receives the high state level from the first inverter input terminal NI1. However, the N-type transistor MNI1 is coupled to the second inverter input terminal NI2. As a result, the first inverter output terminal NO1 has an actual voltage of 1.8 volts due to the turn-on of the N-type transistor MNI1 that couples the first inverter output terminal NO1 and the second inverter input terminal NI2.

The high state level of the second inverter input terminal NI2 turns off the P-type transistor MPI2 of the second inverter 140 and turns on the N-type transistor MNI2 of the second inverter 140 such that the second inverter output terminal NO2 is at the low state level (0). According to the first operation voltage VDD1 of 3.3 volts and the low state level of the first inverter output terminal NO1 having 1.8 volts, the first discharging transistor MND1 turns off. According to the second inverter output terminal NO2 having the low state level, the second discharging transistor MND2 turns off.

On the other hand, when the voltage of the voltage input terminal IO exceeds the predetermined level, e.g., when the voltage input terminal IO not only receives either the power signal or the data signal, but also receives the electrostatic input ES having a large instant voltage, the electrostatic discharge protection circuit 100 operates in a discharging mode. The detection signal DS generated by the voltage-dividing circuit 110 at the detection input terminal DT is at the high state level (1). The output detection signal DSO is at the high state level (1) due to the operation of the voltage detection circuit 120.

The first switch circuit 160 turns on due to the output detection signal DSO and pulls low the first inverter input terminal NI1 such that the first inverter input terminal NI1 is at the low state level (0). The second switch circuit 170 turns off due to the output detection signal DSO such that the second inverter input terminal NI2 is floating (labeled by a symbol “Z”).

The low state level of the first inverter input terminal NI1 turns on the P-type transistor MPI1 of the first inverter 130 and turns off the N-type transistor MNI1 of the first inverter 130 such that the first inverter output terminal NO1 is at the high state level (1) of 3.3 volts. The floating state of the second inverter input terminal NI2 is still lower than the high state level of the first inverter output terminal NO1 such that the P-type transistor MPI2 and the N-type transistor MNI2 of the second inverter 140 turn on simultaneously. Under such a condition, the second inverter output terminal NO2 is at the high state level (1) that is slightly lower than 3.3 volts.

According to the high state level of 3.3 volts of the first inverter output terminal NO1, the first discharging transistor MND1 turns on. According to the high state level of the second inverter output terminal NO2, the second discharging transistor MND2 turns on.

As a result, the output detection signal DSO controls the first switch circuit 160 to turn on and controls the second switch circuit 170 to turn off only when the electrostatic input ES occurs such that the first discharging transistor MND1 and the second discharging transistor MND2 turn on to discharge the voltage input terminal IO. The voltage of the voltage input terminal IO thus decreases. When the detection signal DS generated according to the division of the voltage of the voltage input terminal IO returns to the low state level (0), the electrostatic discharge protection circuit 100 returns to the normal operation mode.

The further detail of the configuration and operation of the electrostatic discharge protection circuit 100 can be referred to the patent application of Taiwan Patent Application number 112111207 (or U.S. patent application Ser. No. 18/600,815). The detail is not described herein.

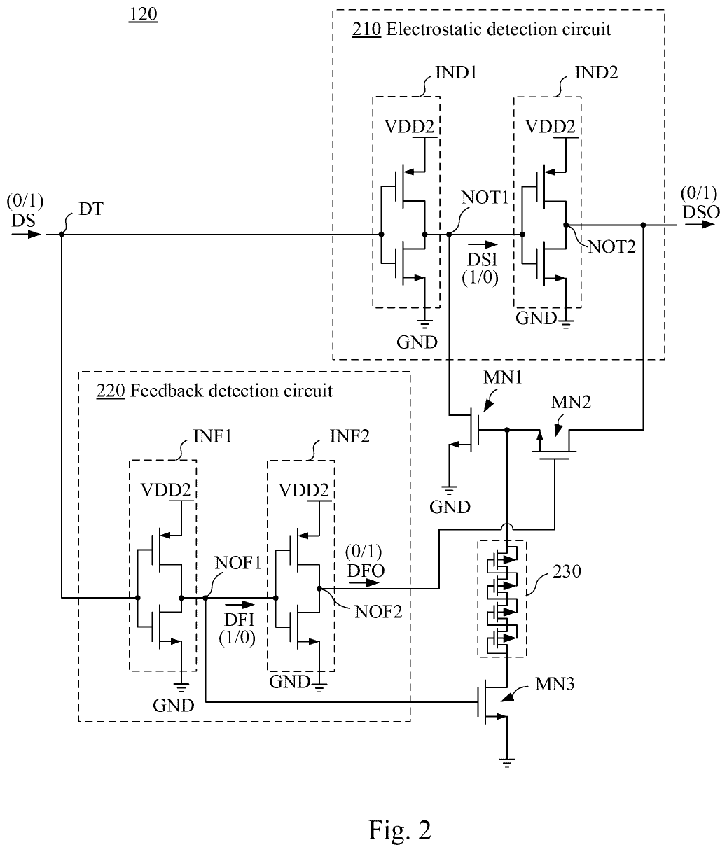

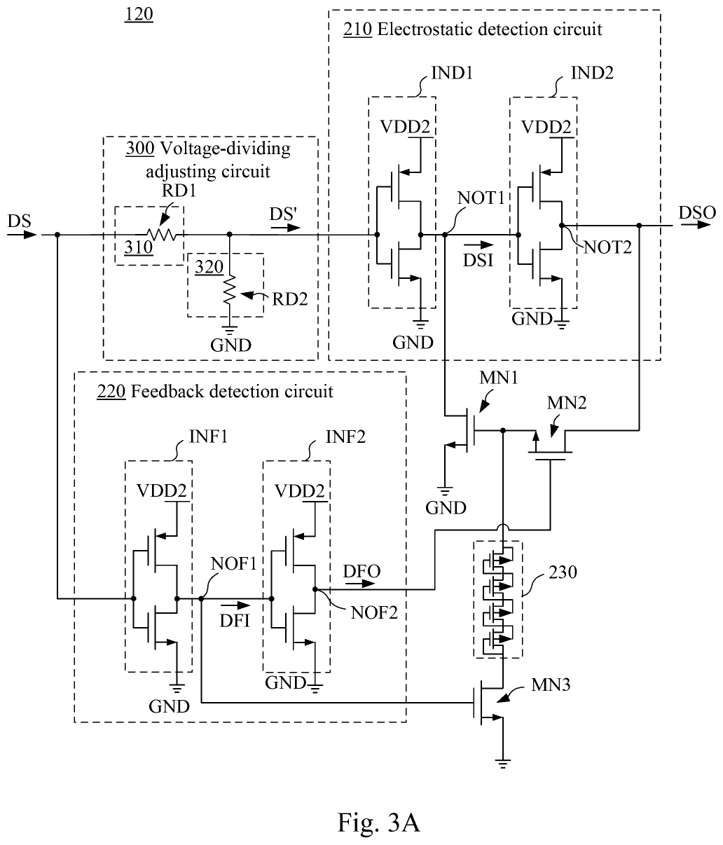

Reference is now made to FIG. 2. FIG. 2 illustrates a more detailed circuit diagram of the voltage detection circuit 120 in FIG. 1 according to an embodiment of the present invention. The voltage detection circuit 120 includes an electrostatic detection circuit 210, a feedback detection circuit 220, a first transistor MN1, a second transistor MN2 and a third transistor MN3.

The electrostatic detection circuit 210 includes a first detection inverter IND1 and a second detection inverter IND2.

The first detection inverter IND1 is configured to receive and invert the detection signal DS from the detection input terminal DT to output an inverse detection signal DSI to a first detection output terminal NOT1. The second detection inverter IND2 is configured to receive and invert an inverse detection signal DSI from the first detection output terminal NOT1 to output the output detection signal DSO to a second detection output terminal NOT2.

The feedback detection circuit 220 is configured to receive and invert the detection signal DS to output an inverse feedback detection signal DFI. In the present embodiment, the feedback detection circuit 220 includes a first feedback inverter INF1 and a second feedback inverter INF2.

The first feedback inverter INF1 is configured to receive and invert the detection signal DS from the detection input terminal DT to output the inverse feedback detection signal DFI to a first feedback output terminal NOF1. The second feedback inverter INF2 is configured to receive and invert the inverse feedback detection signal DFI from the first feedback output terminal NOF1 to output an output feedback detection signal DFO to a second feedback output terminal NOF2.

The first transistor MN1 is electrically coupled between the first detection output terminal NOT1 and the ground terminal GND. In the present embodiment, the first transistor MN1 is an N-type transistor. A first source of the first transistor MN1 is electrically coupled to the first detection output terminal NOT1 and a first drain of the first transistor MN1 is electrically coupled to the ground terminal GND.

The second transistor MN2 is electrically coupled between the second detection output terminal NOT2 and a first gate of the first transistor MN1. In the present embodiment, the second transistor MN2 is an N-type transistor. A second source of the second transistor MN2 is electrically coupled to the second detection output terminal NOT2 and a second drain of the second transistor MN2 is electrically coupled to the first gate of the first transistor MN1.

A second gate of the second transistor MN2 is controlled by the inverse feedback detection signal DFI. In the present embodiment, the second gate of the second transistor MN2 actually receives the output feedback detection signal DFO generated by inverting the inverse feedback detection signal DFI so as to be directly controlled by the output feedback detection signal DFO. As a result, the second gate of the second transistor MN2 is indirectly controlled by the inverse feedback detection signal DFI in the present embodiment.

The third transistor MN3 is electrically coupled between the first gate of the first transistor MN3 and the ground terminal. In the present embodiment, the third transistor MN3 is an N-type transistor. A third source of the third transistor MN3 is electrically coupled to the first gate of the first transistor MN1 and a third drain of the third transistor MN3 is electrically coupled to the ground terminal GND.

A third gate of the third transistor MN3 is controlled by the inverse feedback detection signal DFI. In the present embodiment, the third gate of the third transistor MN3 directly receives the inverse feedback detection signal DFI and is controlled thereby.

In the connection relations described above, other components may be disposed between any two of the components described above under the condition that the function thereof is not affected. For example, the voltage detection circuit 120 may selectively include a load circuit 230 illustrated in FIG. 2. The third transistor MN3 is electrically coupled to the first gate of the first transistor MN1 through the load circuit 230. In the example of FIG. 2, the load circuit 230 is illustrated as a plurality of load transistors coupled in series. However, in different embodiments, the load circuit 230 may include at least one resistor, at least one load transistor or at least one diode. Besides, in different embodiments, the load circuit 230 can be implemented by N-type transistors, P-type transistors or a plurality of transistors including both N-type transistors and P-type transistors.

The configuration of the source, the drain and the gate of the N-type transistor can be understood by those of ordinary skill in the art. As a result, the source, the drain and the gate of these transistors are not labeled in the figures.

The normal operation mode and the discharging mode that the voltage detection circuit 120 operates according to the states, i.e., the low state and the high state, of the detection signal DS are described in the following paragraphs. In FIG. 1, the logic states of each of the signals and the circuit nodes in the normal operation mode and the discharging mode are labeled, in which “1” stands for the high state and “0” stands for the low state.

When the detection signal DS is at the low state (0), the voltage detection circuit 120 operates in the normal operation mode. The inverse detection signal DSI is at the high state (1) due to the operation of the first detection inverter IND1. The output detection signal DSO is at the low state (0) due to the operation of the second detection inverter IND2. The inverse feedback detection signal DFI is at the high state (1) due to the operation of the first feedback inverter INF1. The output feedback detection signal DFO is at the low state (0) due to the operation of the second feedback inverter INF2.

The inverse feedback detection signal DFI at the high state indirectly controls the second transistor MN2 to turn off through the use of the output feedback detection signal DFO at the low state, and directly controls the third transistor MN3 to turn on. The second transistor MN2 that turns off stops to charge the first gate and the third transistor MN3 that turns on discharge the first gate such that the first transistor MN1 turns off. The first transistor MN1 that turns off stops to discharge the first detection output terminal NOT1 to keep the inverse detection signal DSI outputted by the first detection output terminal NOT1 at the high state (1). In the operation described above, the speed of the discharging performed on the first gate by the third transistor MN3 that turns on is determined by a resistance of the load circuit 230.

On the other hand, when the detection signal DS is at the high state (1), the voltage detection circuit 120 operates in the discharging mode. The inverse detection signal DSI is at the low state (0) due to the operation of the first detection inverter IND1. The output detection signal DSO is at the high state (1) due to the operation of the second detection inverter IND2. The inverse feedback detection signal DFI is at the low state (0) due to the operation of the first feedback inverter INF1. The output feedback detection signal DFO is at the high state (1) due to the operation of the second feedback inverter INF2.

The inverse feedback detection signal DFI at the low state indirectly controls the second transistor MN2 to turn on and directly controls the third transistor MN3 to turn off. The second transistor MN2 that turns on transmits the output detection signal DSO at the high state to first gate to charge the first gate such that the first transistor MN1 turns on. The first transistor MN1 that turns on discharges the first detection output terminal NOT1 such that the inverse detection signal DSI outputted by the first detection output terminal NOT1 is at the low state (0).

It is appreciated that after the first discharging transistor MND1 and the second discharging transistor MND2 discharges the voltage input terminal IO for a period of time, the voltage of the voltage input terminal IO drops such that the detection signal DS generated according to the division of the voltage of the voltage input terminal IO returns to the low state level (0). The electrostatic discharge protection circuit 100 thus returns to the normal operation mode.

Based on the configuration described above, when the electrostatic discharge protection circuit 100 and the voltage detection circuit 120 thereof operate in the discharging mode, the voltage of the voltage input terminal IO drops to the low state level due to the discharging performed by the first discharging transistor MND1 and the second discharging transistor MND2 such that the first detection inverter IND1 supposes to output the high state level at the first detection output terminal NOT1. However, the first transistor MN1 still turns on and keeps pull low the voltage level of the first detection output terminal NOT1 to keep the output detection signal DSO at the high state level. The first discharging transistor MND1 and the second discharging transistor MND2 thus have a longer discharging time such that the electric charges accumulated at the voltage input terminal IO due to the electrostatic input ES can be discharged with a sufficient time length.

On the contrary, when the voltage of the voltage input terminal IO drops due to the discharging performed by the first discharging transistor MND1 and the second discharging transistor MND2 such that the detection signal DS generated according to the division of the voltage of the voltage input terminal IO returns to the low state level (0), the turn-off of the first transistor MN1 allows the electric charges at the first detection output terminal NOT1 to be stored and accumulated to increase the voltage of the first detection output terminal NOT1 and completely turn off the voltage detection circuit 120.

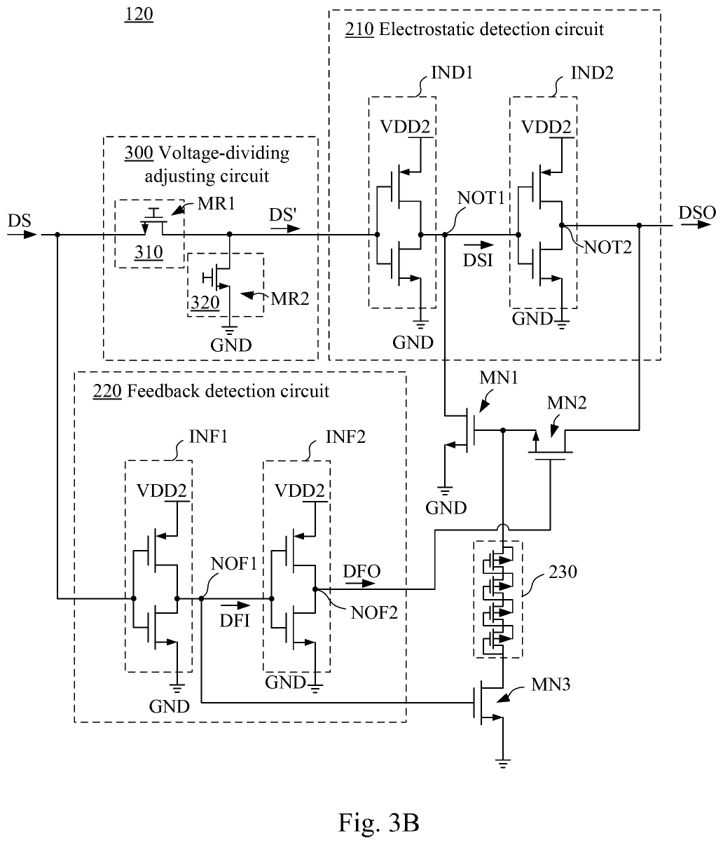

Reference is now made to FIG. 3A, FIG. 3B and FIG. 3C. FIG. 3A, FIG. 3B and FIG. 3C illustrate detailed circuit diagrams of the voltage detection circuit 120 in FIG. 1 according to another embodiment of the present invention. The voltage detection circuit 120 in FIG. 3A, FIG. 3B and FIG. 3C includes the electrostatic detection circuit 210, the feedback detection circuit 220, the first transistor MN1, the second transistor MN2 and the third transistor MN3. The configuration and the operation of these components are identical to those illustrated in FIG. 2. The identical configuration and operation are thus not described herein.

The voltage detection circuit 120 in FIG. 3A, FIG. 3B and FIG. 3C further includes a voltage-dividing adjusting circuit 300. The voltage-dividing adjusting circuit 300 is electrically coupled between the detection input terminal DT and the first detection inverter IND1.

In an embodiment, the voltage-dividing adjusting circuit 300 includes a first resistive element 310 and a second resistive element 320. The first resistive element 310 is electrically coupled between detection input terminal DT and the first detection inverter IND1. The second resistive element 320 is electrically coupled between first detection inverter IND1 and the ground terminal GND.

Each of the first resistive element 310 and the second resistive element 320 is a resistor, a load transistor or a diode. In FIG. 3A, an embodiment that includes the first resistive element 310 implemented by a resistor RD1 and the second resistive element 320 implemented by a resistor RD2 is illustrated. In FIG. 3B, an embodiment that includes the first resistive element 310 implemented by a load transistor MR1 and the second resistive element 320 implemented by a load transistor MR2 is illustrated. In FIG. 3C, an embodiment that includes the first resistive element 310 implemented by three diodes D1˜D3 and the second resistive element 320 implemented by three diodes D4˜D6 is illustrated.

By disposing the voltage-dividing adjusting circuit 300, a first voltage level of the detection signal DS' received by the electrostatic detection circuit 210 through the voltage-dividing adjusting circuit 300 is smaller than a second voltage level of the detection signal DS received by the feedback detection circuit 220. As a result, the feedback detection circuit 220 may detect a sufficiently high voltage first such that the second transistor MN2 turns on before the electrostatic detection circuit 210 begins to operate to guarantee that the feedback detection circuit 220 activates before the first discharging transistor MND1 and the second discharging transistor MND2 in FIG. 1 turn on. The stability of the voltage detection circuit 120 is thus increased.

It is appreciated that the number and the type of the components illustrated in the figures described above are merely an example. In practical implementation, the voltage-dividing adjusting circuit 300 may include different numbers and types of the components depending on the voltage level required to be received by the electrostatic detection circuit 210. The present invention is not limited thereto.

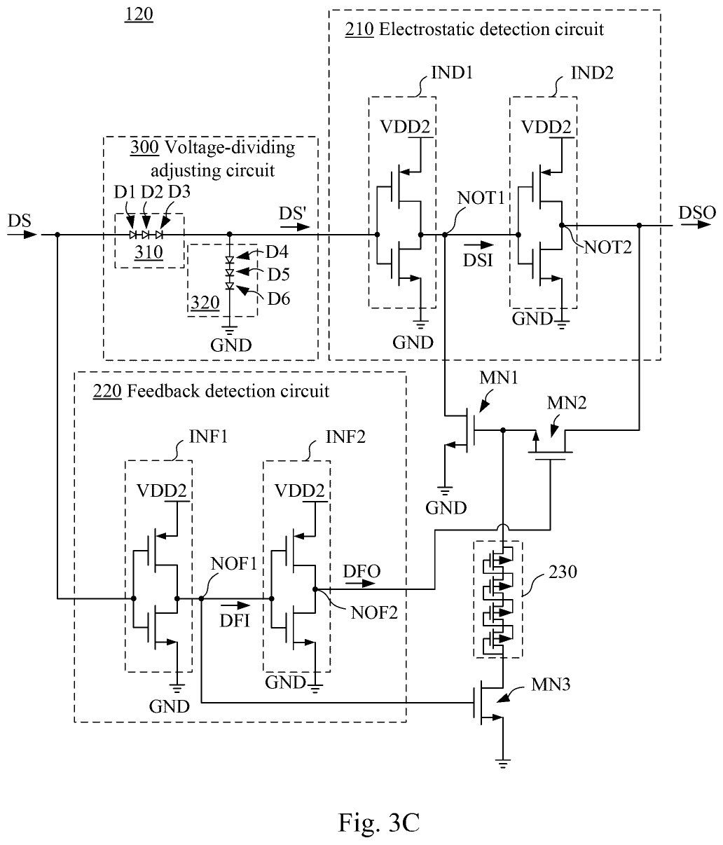

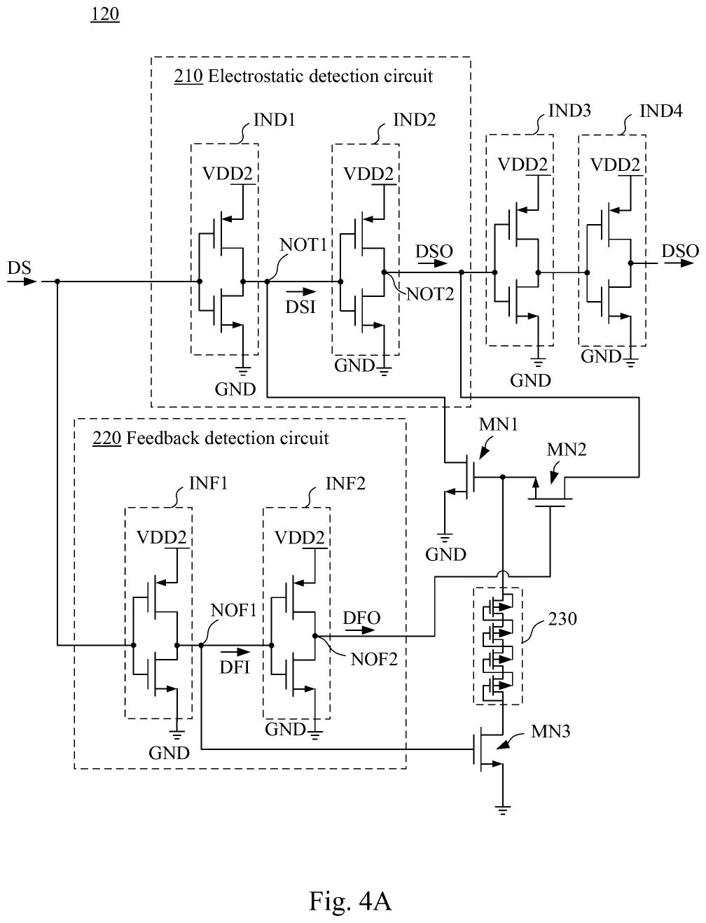

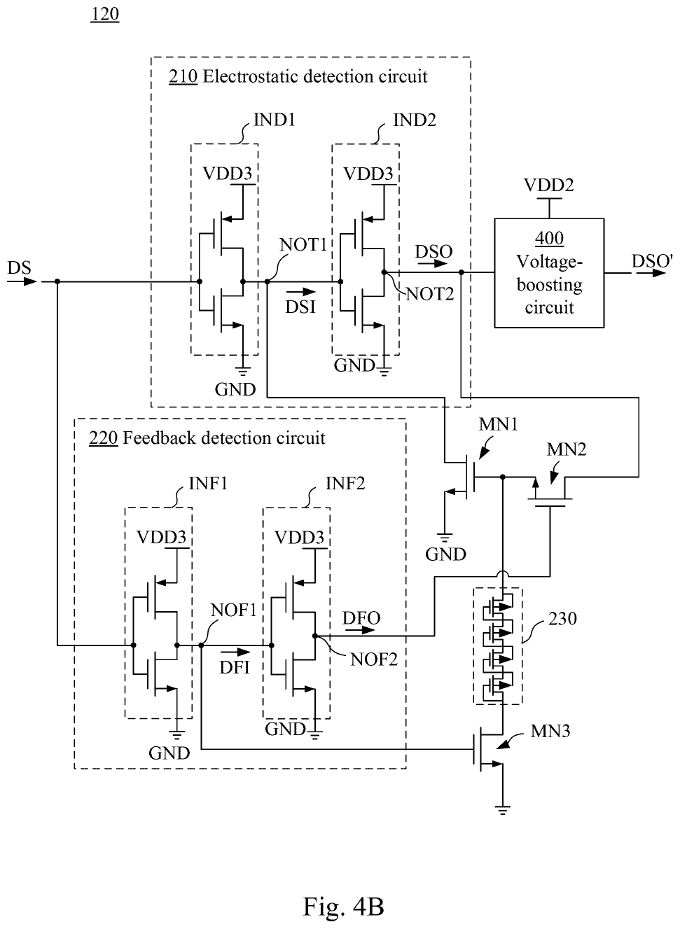

Reference is now made to FIG. 4A and FIG. 4B. FIG. 4A and FIG. 4B illustrate detailed circuit diagrams of the voltage detection circuit 120 in FIG. 1 according to yet another embodiment of the present invention. The voltage detection circuit 120 in FIG. 4A and FIG. 4B includes the electrostatic detection circuit 210, the feedback detection circuit 220, the first transistor MN1, the second transistor MN2 and the third transistor MN3. The configuration and the operation of these components are identical to those illustrated in FIG. 2. The identical configuration and operation are thus not described herein.

The voltage detection circuit 120 in FIG. 4A selectively further includes a plurality of detection inverters IND3˜IND4 coupled in series. The detection inverters IND3˜IND4 are electrically coupled to the second detection output terminal NOT2 to receive and output the output detection signal DSO. The detection inverters IND3˜IND4 serve as buffers to increase the strength of the output detection signal DSO.

The voltage detection circuit 120 in FIG. 4B selectively further includes a voltage-boosting circuit 400. The voltage-boosting circuit 400 is electrically coupled to the second detection output terminal NOT2 to receive and output the output detection signal DSO′ such that the first switch circuit 160 and the second switch circuit 170 in FIG. 1 actually receives the output detection signal DSO′ having the voltage boosted. The detailed configuration and operation of the voltage-boosting circuit 400 can be referred to the patent application of Taiwan Patent Application number 112111207 (or U.S. patent application Ser. No. 18/600,815). The detail is not described herein.

In an embodiment, the voltage-boosting circuit 400 operates according to a second operation voltage higher than a first operation voltage of the electrostatic detection circuit 210 and the feedback detection circuit 220. More specifically, in an embodiment, the voltage detection circuit 120 is separated into two parts. A part of the voltage detection circuit 120 includes the voltage-boosting circuit 400 that operates according to the second operation voltage VDD2 that is 1.8 volts. The other part of the voltage detection circuit 120 includes the electrostatic detection circuit 210 and the feedback detection circuit 220 that operate according to a third operation voltage VDD3 of 0.9 volts. As a result, the voltage detection circuit 120 is configured to boost the output detection signal DSO generated by the electrostatic detection circuit 210 from 0.9 volts to 1.8 volts.

The electrostatic detection circuit 210 and the feedback detection circuit 220 that operate according to a lower voltage have faster response speed and thus are more sensitive with regard to the voltage detection. However, the power-on times of the circuit blocks having different operation voltages in the voltage detection circuit 120 are different due to different power-on speeds. In some approaches, when the voltage detection circuit 120 only includes the first transistor MN1 and the first gate thereof is directly controlled by the output detection signal DSO, the first transistor MN1 may turn on falsely due to the unknown state generated under the condition that the voltage-boosting circuit 400 is not powered yet. Under such a condition, the voltage detection circuit 120 of the present invention prevents the first transistor MN1 from falsely turning on according to the disposition of the second transistor MN2 and the third transistor MN3.

Part of the components in the embodiment illustrated in FIG. 2, e.g., the first transistor MN1, the second transistor MN2 and the third transistor MN3, can be implemented by P-type transistors under the condition that the circuit design is adjusted properly. The embodiment that the second transistor MN2 is implemented by the P-type transistor is described as an example in the following paragraphs.

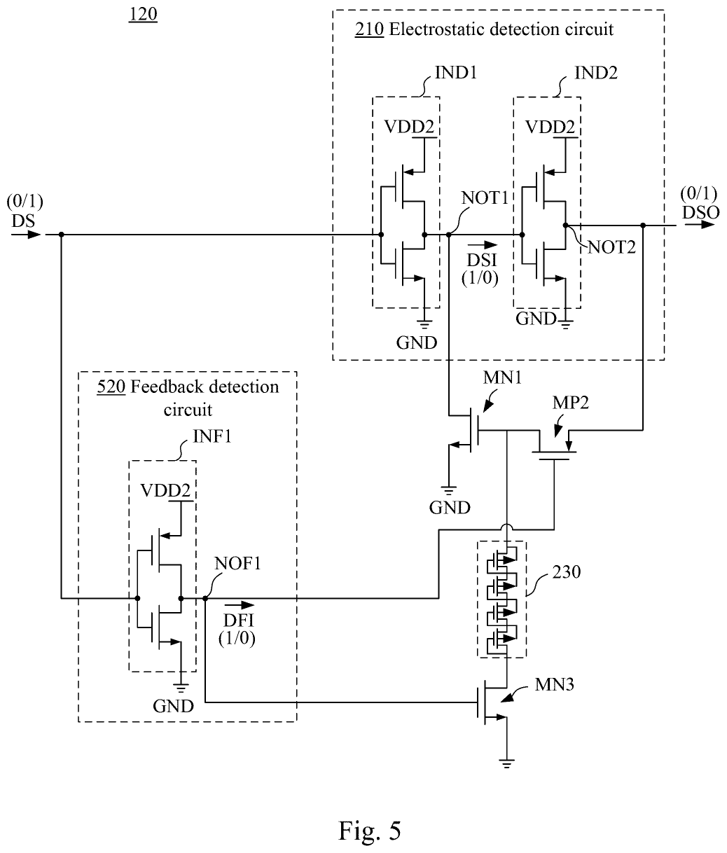

Reference is now made to FIG. 5. FIG. 5 illustrates a detailed circuit diagram of the voltage detection circuit 120 in FIG. 1 according to still another embodiment of the present invention. The voltage detection circuit 120 in FIG. 5 includes the electrostatic detection circuit 210, the first transistor MN1 and the third transistor MN3. The configuration and the operation of these components are identical to those illustrated in FIG. 2. The identical configuration and operation are thus not described herein.

In the present embodiment, the voltage detection circuit 120 includes a feedback detection circuit 520 and a second transistor MP2.

The second transistor MP2 is electrically coupled between the second detection output terminal NOT2 and the first gate of the first transistor MN1. In the present embodiment, the second transistor MP2 is a P-type transistor. The second drain of the second transistor MP2 is electrically coupled to the second detection output terminal NOT2 and the second source of the second transistor MN2 is electrically coupled to the first gate of the first transistor MN1.

The feedback detection circuit 520 only includes the first feedback inverter INF1 to receive and invert the detection signal DS from the detection input terminal DT to output the inverse feedback detection signal DFI to the first feedback output terminal NOF1. Under such a condition, similar to the operation of the third gate of the third transistor MN3, the second gate of the second transistor MP2 directly receives the inverse feedback detection signal DFI and is controlled thereby. The operation of the second transistor MP2 in the normal operation mode and the discharging mode is identical to the operation of the second transistor MN2 in FIG. 2. The detail is not described herein.

The voltage detection circuit in the embodiments described above can be used in other designs of the electrostatic discharge protection circuit.

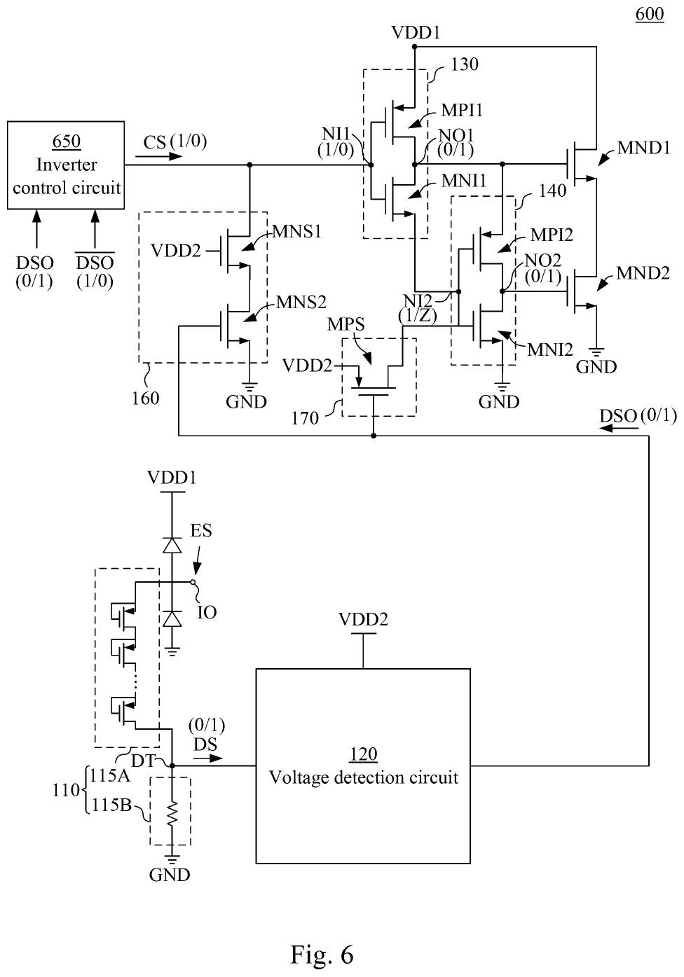

Reference is now made to FIG. 6. FIG. 6 illustrates a circuit diagram of an electrostatic discharge protection circuit 600 according to another embodiment of the present invention. Similar to the electrostatic discharge protection circuit 100 in FIG. 1, the electrostatic discharge protection circuit 600 includes the voltage-dividing circuit 110, the voltage detection circuit 120, the first inverter 130, the second inverter 140, the first switch circuit 160, the second switch circuit 170, the first discharging transistor MND1 and the second discharging transistor MND2. The configuration and the operation of these components are identical to those illustrated in FIG. 1. The identical configuration and operation are thus not described herein.

In the present embodiment, the electrostatic discharge protection circuit 600 includes an inverter control circuit 650. The inverter control circuit 650 is configured to operate according to the first operation voltage VDD1 to perform voltage boosting on the output detection signal DSO and generate a control signal CS having a phase inverse to the output detection signal DSO to the first inverter input terminal NI1.

Besides the inverter control circuit 650 that replaces the RC circuit 150 in the electrostatic discharge protection circuit 100, the other operations of the electrostatic discharge protection circuit 600 are identical to those of the electrostatic discharge protection circuit 100. The further detail of the configuration and operation of the electrostatic discharge protection circuit 600 and the inverter control circuit 650 included thereby can be referred to the patent application of Taiwan Patent Application number 112111220 (or U.S. patent application Ser. No. 18/600,817). The detail is not described herein.

The voltage detection circuit in the embodiments described above can be used in other circuits in other embodiments. The voltage detection circuit of the present invention is not limited in the application of the electrostatic discharge protection circuit.

It is appreciated that the embodiments described above are merely an example. In other embodiments, it is appreciated that many modifications and changes may be made by those of ordinary skill in the art without departing, from the spirit of the invention.

In summary, the electrostatic discharge protection circuit and the voltage detection circuit thereof dispose a first transistor in the voltage detection circuit to increase the electrostatic discharging time and enhance the turn-off of the electrostatic discharge protection mechanism. Further, a feedback detection circuit is disposed to control a second transistor and a third transistor to further control the turn-on and turn-off of a first transistor to prevent the first transistor from falsely turning on in some usage scenarios and from the occurrence of incapability to turn off.

The aforementioned descriptions represent merely the preferred embodiments of the present disclosure, without any intention to limit the scope of the present disclosure thereto. Various equivalent changes, alterations, or modifications based on the claims of present disclosure are all consequently viewed as being embraced by the scope of the present disclosure.

What is claimed is:

1. A voltage detection circuit comprising:
an electrostatic detection circuit comprising:
a first detection inverter configured to receive and invert a detection signal from a detection input terminal to output an inverse detection signal to a first detection output terminal; and
a second detection inverter configured to receive and invert the inverse detection signal from the first detection output terminal to output an output detection signal to a second detection output terminal;
a feedback detection circuit configured to receive and invert the detection signal to output an inverse feedback detection signal;
a first transistor electrically coupled between the first detection output terminal and a ground terminal;
a second transistor electrically coupled between the second detection output terminal and a first gate of the first transistor, and a second gate of the second transistor is controlled by the inverse feedback detection signal; and
a third transistor electrically coupled between the first gate and ground terminal, wherein a third gate of the third transistor is controlled by the inverse feedback detection signal;
wherein when the detection signal is at a high state, the inverse feedback detection signal controls the second transistor to turn on and controls the third transistor to turn off, and the second transistor transmits the output detection signal to the first gate to control the first transistor to turn on; and
when the detection signal is at a low state, the inverse feedback detection signal controls the second transistor to turn off and controls the third transistor to turn on, and the third transistor discharges the first gate to control the first transistor to turn off.

2. The voltage detection circuit of claim 1, further comprising a voltage-dividing adjusting circuit electrically coupled between the detection input terminal and the first detection inverter such that a first voltage level of the detection signal that the electrostatic detection circuit receives through the voltage-dividing adjusting circuit is smaller than a second voltage level of the detection signal received by the feedback detection circuit.

3. The voltage detection circuit of claim 2, wherein the voltage-dividing adjusting circuit comprises:
a first resistive element electrically coupled between the detection input terminal and the first detection inverter; and
a second resistive element electrically coupled between the first detection inverter and the ground terminal.

4. The voltage detection circuit of claim 1, further comprising a load circuit, and the third transistor is electrically coupled to the first gate through the load circuit.

5. The voltage detection circuit of claim 1, wherein the second transistor is a P-type transistor to be directly controlled by the inverse feedback detection signal, and the feedback detection circuit comprises:
a first feedback inverter configured to receive and invert the detection signal from the detection input terminal to output an inverse feedback detection signal to a first feedback output terminal.

6. The voltage detection circuit of claim 1, wherein the second transistor is an N-type transistor and the feedback detection circuit comprises:
a first feedback inverter configured to receive and invert the detection signal from the detection input terminal to output an inverse feedback detection signal to a first feedback output terminal; and
a second feedback inverter configured to receive and invert the inverse feedback detection signal from the first feedback output terminal to output an output feedback detection signal to a second feedback output terminal such that the second transistor is directly controlled by the output feedback detection signal.

7. The voltage detection circuit of claim 1, wherein the voltage detection circuit further comprises a plurality of detection inverters coupled in series and electrically coupled to the second detection output terminal to receive and output the output detection signal.

8. The voltage detection circuit of claim 1, wherein the voltage detection circuit further comprises a voltage-boosting circuit electrically coupled to the second detection output terminal to receive and output the output detection signal, wherein the voltage-boosting circuit operates according to an operation voltage higher than the operation voltage of the electrostatic detection circuit and the feedback detection circuit.

9. An electrostatic discharge protection circuit comprising:
a voltage-dividing circuit electrically coupled to a voltage input terminal to generate a detection signal at a detection input terminal, wherein the voltage input terminal is further electrically coupled to a first voltage feeding terminal configured to feed a first voltage;
a voltage detection circuit comprising:
an electrostatic detection circuit comprising:
a first detection inverter configured to receive and invert a detection signal from a detection input terminal to output an inverse detection signal to a first detection output terminal; and
a second detection inverter configured to receive and invert the inverse detection signal from the first detection output terminal to output an output detection signal to a second detection output terminal;
a feedback detection circuit configured to receive and invert the detection signal to output an inverse feedback detection signal;
a first transistor electrically coupled between the first detection output terminal and a ground terminal;
a second transistor electrically coupled between the second detection output terminal and a first gate of the first transistor, and a second gate of the second transistor is controlled by the inverse feedback detection signal; and
a third transistor electrically coupled to the first gate and the ground terminal and a third gate of the third transistor is controlled by the inverse feedback detection signal, wherein when the detection signal is at a high state, the inverse feedback detection signal controls the second transistor to turn on and controls the third transistor to turn off and the second transistor transmits the output detection signal to the first gate to control the first transistor to turn on, and when the detection signal is at a low state, the inverse feedback detection signal controls the second transistor to turn off and controls the third transistor to turn on, and the third transistor discharges the first gate to control the first transistor to turn off;
a first inverter having a first inverter input terminal and a first inverter output terminal and electrically coupled between the first voltage feeding terminal and a second inverter input terminal;
a second inverter having the second inverter input terminal and a second inverter output terminal and electrically coupled between the first inverter output terminal and the ground terminal;
a RC circuit comprising a resistor and a capacitor circuit, wherein the capacitor circuit is electrically coupled to the first voltage feeding terminal through the resistor to be charged accordingly and provides electric charges to the first inverter input terminal and the second inverter input terminal;
a first switch circuit electrically coupled between one the first inverter input terminal and the second inverter input terminal and the ground terminal;
a second switch circuit electrically coupled between a second voltage feeding terminal configured to feed a second voltage and the second inverter input terminal; and
a first discharging transistor and a second discharging transistor electrically coupled in series between the first voltage feeding terminal and the ground terminal, and respectively controlled by voltages of the first inverter output terminal and the second inverter output terminal;
wherein the output detection signal controls the first switch circuit to turn on and controls the second switch circuit to turn off when an electrostatic discharge input occurs to the voltage input terminal, such that the first discharging transistor and the second discharging transistor turn on to discharge the voltage input terminal.

10. The electrostatic discharge protection circuit of claim 9, wherein the voltage detection circuit further comprises a voltage-dividing adjusting circuit electrically coupled between the detection input terminal and the first detection inverter such that a first voltage level of the detection signal that the electrostatic detection circuit receives through the voltage-dividing adjusting circuit is smaller than a second voltage level of the detection signal received by the feedback detection circuit.

11. The electrostatic discharge protection circuit of claim 10, wherein the voltage-dividing adjusting circuit comprises:
a first resistive element electrically coupled between the detection input terminal and the first detection inverter; and
a second resistive element electrically coupled between the first detection inverter and the ground terminal.

12. The electrostatic discharge protection circuit of claim 9, wherein the voltage detection circuit further comprises a load circuit and the third transistor is electrically coupled to the first gate through the load circuit.

13. The electrostatic discharge protection circuit of claim 9, wherein the second transistor is a P-type transistor to be directly controlled by the inverse feedback detection signal, and the feedback detection circuit comprises:
a first feedback inverter configured to receive and invert the detection signal from the detection input terminal to output an inverse feedback detection signal to a first feedback output terminal.

14. The electrostatic discharge protection circuit of claim 9, wherein the second transistor is an N-type transistor and the feedback detection circuit comprises:
a first feedback inverter configured to receive and invert the detection signal from the detection input terminal to output an inverse feedback detection signal to a first feedback output terminal; and
a second feedback inverter configured to receive and invert the inverse feedback detection signal from the first feedback output terminal to output an output feedback detection signal to a second feedback output terminal such that the second transistor is directly controlled by the output feedback detection signal.

15. The electrostatic discharge protection circuit of claim 9, wherein the voltage detection circuit further comprises a plurality of detection inverters coupled in series and electrically coupled to the second detection output terminal to receive and output the output detection signal.

16. The electrostatic discharge protection circuit of claim 9, wherein the voltage detection circuit further comprises a voltage-boosting circuit electrically coupled to the second detection output terminal to receive and output the output detection signal, wherein the voltage-boosting circuit operates according to an operation voltage higher than the operation voltage of the electrostatic detection circuit and the feedback detection circuit.

17. An electrostatic discharge protection circuit comprising:
a voltage-dividing circuit electrically coupled to a voltage input terminal to generate a detection signal at a detection input terminal, wherein the voltage input terminal is further electrically coupled to a first voltage feeding terminal configured to feed a first voltage;
a voltage detection circuit comprising:
an electrostatic detection circuit comprising:
a first detection inverter configured to receive and invert a detection signal from a detection input terminal to output an inverse detection signal to a first detection output terminal; and
a second detection inverter configured to receive and invert the inverse detection signal from the first detection output terminal to output an output detection signal to a second detection output terminal;
a feedback detection circuit configured to receive and invert the detection signal to output an inverse feedback detection signal;
a first transistor electrically coupled between the first detection output terminal and a ground terminal;
a second transistor electrically coupled between the second detection output terminal and a first gate of the first transistor, and a second gate of the second transistor is controlled by the inverse feedback detection signal; and
a third transistor electrically coupled to the first gate and the ground terminal and a third gate of the third transistor is controlled by the inverse feedback detection signal, wherein when the detection signal is at a high state, the inverse feedback detection signal controls the second transistor to turn on and controls the third transistor to turn off and the second transistor transmits the output detection signal to the first gate to control the first transistor to turn on, and when the detection signal is at a low state, the inverse feedback detection signal controls the second transistor to turn off and controls the third transistor to turn on, and the third transistor discharges the first gate to control the first transistor to turn off;
a first inverter having a first inverter input terminal and a first inverter output terminal and electrically coupled between the first voltage feeding terminal and a second inverter input terminal;
a second inverter having the second inverter input terminal and a second inverter output terminal and electrically coupled between the first inverter output terminal and the ground terminal;
an inverter control circuit configured to operate according to the first voltage to perform voltage boosting on the output detection signal and generate a control signal having a phase inverse to the output detection signal to the first inverter input terminal;
a first switch circuit electrically coupled between one the first inverter input terminal and the second inverter input terminal and the ground terminal;
a second switch circuit electrically coupled between a second voltage feeding terminal configured to feed a second voltage and the second inverter input terminal; and
a first discharging transistor and a second discharging transistor electrically coupled in series between the first voltage feeding terminal and the ground terminal, and respectively controlled by voltages of the first inverter output terminal and the second inverter output terminal;
wherein the output detection signal controls the first switch circuit to turn on and controls the second switch circuit to turn off when an electrostatic discharge input occurs to the voltage input terminal, such that the first discharging transistor and the second discharging transistor turn on to discharge the voltage input terminal.
